(19) United States
(12) Patent Application Publication
(10) Pub. No.: US 2023/0126904 A1
(43) Pub. Date: Apr. 27, 2023

(54) ELECTRONIC DEVICE

(71) Applicant: Innolux Corporation, Miao-Li County (TW)

(72) Inventors: Ming-Che Huang, Miao-Li County (TW); Po-Hsun Shen, Miao-Li County (TW); Chi-Chau Lin, Miao-Li County (TW)

(73) Assignee: Innolux Corporation, Miao-Li County (TW)

(21) Appl. No.: 17/947,182

(22) Filed: Sep. 19, 2022

(30) Foreign Application Priority Data
Oct. 25, 2021 (CN) 202111239987.9

(51) Int. Cl. H05K 5/02

(52) U.S. Cl. CPC H05K 5/0214

(57) ABSTRACT

An electronic device is provided. The electronic device includes a casing and a ventilation structure. The ventilation structure is located on the casing and has a first opening, a second opening, and a ventilation channel connected between the first opening and the second opening. The ventilation structure includes a first barrier, a second barrier, and a third barrier located in the ventilation channel. The second barrier is located between the first barrier and the third barrier, and the first barrier, the second barrier, and the third barrier at least partially overlap in an extending direction of the ventilation channel.

### CROSS-REFERENCE TO RELATED APPLICATION

This application claims the priority benefit of China application serial no. 202111239987.9, filed on Oct. 25, 2021. The entirety of the above-mentioned patent application is hereby incorporated by reference herein and made a part of this specification.

### BACKGROUND

### Technical Field

The disclosure relates to an electronic device.

### Description of Related Art

The innovation and development of electronic devices make life much more convenient. There are more and more places where electronic devices can be applied. In addition to portable electronic devices and electronic devices used indoors, many electronic devices can be installed and fixed outdoors, such as outdoor displays and outdoor information stations. The electronic devices installed in an outdoor environment are required to have capabilities such as good weather resistance, foreign matter intrusion resistance, and waterproof capability. In terms of waterproof capability, the use of a closed casing can reduce the intrusion of external water into an electronic product but may lead to poor heat dissipation of the electronic product.

### SUMMARY

The disclosure provides an electronic device that effectively prevents external water from entering the electronic device or maintains the heat dissipation performance of the electronic device.

According to an exemplary embodiment of the disclosure, an electronic device includes a casing and a ventilation structure. The ventilation structure is located on the casing and has a first opening, a second opening, and a ventilation channel connected between the first opening and the second opening. The ventilation structure includes a first barrier, a second barrier, and a third barrier located in the ventilation channel. The second barrier is located between the first barrier and the third barrier, and the first barrier, the second barrier, and the third barrier at least partially overlap in an extending direction of the ventilation channel.

In order to make the above-mentioned and other features and advantages of the disclosure easier to understand, exemplary embodiments will be described in detail hereinafter with reference to the accompanying drawings.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a partial schematic view of the electronic device according to an embodiment of the disclosure.

FIG. 2 is a partial enlarged view of the ventilation structure 110 of the electronic device of FIG. 1.

FIG. 3 is a schematic view of the first protection member according to an embodiment of the disclosure.

FIG. 4 is a schematic view of the second protection member according to an embodiment of the disclosure.

FIG. 5 is a side view of the ventilation structure of the electronic device of FIG. 1 along the line I-I.

FIG. 6 is a schematic view of the ventilation structure according to an embodiment of the disclosure.

FIG. 7 is a partial schematic view of the electronic device according to an embodiment of the disclosure.

FIG. 8 is a schematic view of the ventilation structure of the electronic device of FIG. 7.

FIG. 9 is a schematic cross-sectional view of the ventilation structure of FIG. 8 along the line II-II.

### DETAILED DESCRIPTION OF DISCLOSED EMBODIMENTS

Reference will now be made in detail to the exemplary embodiments of the disclosure, examples of which are illustrated in the accompanying drawings. Whenever possible, the same reference numerals are used to represent the same or similar parts in the accompanying drawings and description.

In the disclosure, when one structure (or layer, component, or substrate) is described as being located on/above another structure (or layer, component, or substrate), it may mean that the two structures are adjacent and directly connected to each other, or mean that the two structures are adjacent but not directly connected to each other. “Being not directly connected to each other” means that there is at least one intermediate structure (or intermediate layer, intermediate component, intermediate substrate, or intermediate space) between the two structures, wherein a lower surface of one structure is adjacent or directly connected to an upper surface of the intermediate structure and an upper surface of the another structure is adjacent or directly connected to a lower surface of the intermediate structure, and the intermediate structure may be composed of a single-layer or multi-layer solid structure or non-solid structure, which is not limited in the disclosure. In the disclosure, when a certain structure is disposed “on” another structure, it may mean that the certain structure is “directly” on the another structure or that the certain structure is “indirectly” on the another structure. That is, at least one structure is sandwiched between the certain structure and the another structure.

Electrical connection or coupling described in the disclosure may both refer to direct connection or indirect connection. In the case of direct connection, terminals of elements on two circuits are directly connected or connected to each other by a conductive wire segment. In the case of indirect connection, there are other elements between the terminals of the elements on the two circuits, such as switches, diodes, capacitors, inductors, resistors, other suitable elements, or a combination thereof, but the disclosure is not limited thereto.

In the disclosure, thickness, length, and width may be measured by using an optical microscope, or thickness may be obtained by measuring a cross-sectional image in an electron microscope, but the disclosure is not limited thereto. Moreover, there may be a certain error between any two values or directions used for comparison. If the first value is equal to the second value, it implies that there may be an error of about 10% or 5% or 3% between the first value and the second value.

It should be noted that, in the following embodiments, features in several different embodiments may be replaced, recombined, or mixed to complete other embodiments without departing from the spirit of the disclosure. As long as the features of various embodiments do not contradict the spirit of the disclosure or conflict with each other, they may be combined arbitrarily. In the disclosure, an electronic device may include a display device, an antenna device, a sensing device, or a splicing device, but not limited thereto. The electronic device may be a bendable or flexible electronic device. The electronic device may include, for example, a liquid crystal or a light-emitting diode (LED). The light-emitting diode may include, for example, an organic light-emitting diode (OLED), a mini LED, a micro LED, a quantum dot (QD) LED (e.g., QLED or QDLED), fluorescence, phosphor, or other suitable materials, which may be arranged or combined arbitrarily, but not limited thereto. The antenna device may include, for example, a liquid crystal antenna, but not limited thereto. The splicing device may include, for example, a display splicing device or an antenna splicing device, but not limited thereto. It is noted that the electronic device may be any combination of the above, but not limited thereto.

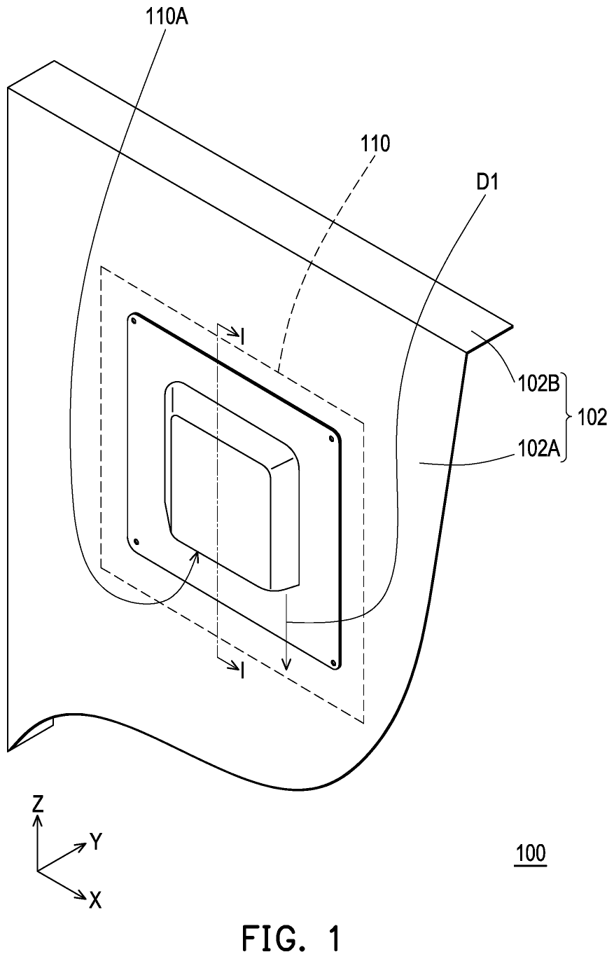

FIG. 1 is a partial schematic view of the electronic device according to an embodiment. The angle of FIG. 1 shows the appearance of the electronic device and the appearance of the back surface of the electronic device. In FIG. 1, the electronic device 100 includes a casing 102 and a ventilation structure 110. The casing 102 is, for example, an outer casing of the electronic device 100, and may include at least a back plate 102A and a side wall 102B. The side wall 102B surrounds the periphery of the back plate 102A to enclose an inner space, and individual electronic components of the electronic device 100 may be installed in the inner space enclosed by the back plate 102A and the side wall 102B. In some embodiments, the electronic device 100 may be a display whose individual electronic components include a display panel, a backlight module, a drive circuit board, a speaker, a touch panel, an optical sensor, or any combination thereof (not shown). The ventilation structure 110 is located on the casing 102 and is arranged on the back surface of the electronic device 100, but not limited thereto.

As can be understood from FIG. 1, the ventilation structure 110 at least has a first opening 110A. The first opening 110A of the ventilation structure 110 may allow air communication between the inner space of the electronic device 100 and the outside. For example, when the ventilation structure 110 is used with exhaust equipment, the hot air in the inner space of the electronic device 100 may be discharged from the first opening 110A to the outside through the exhaust equipment; and when the ventilation structure 110 is used with blower equipment, the blower equipment may suck in air at a lower temperature from the outside to reduce the temperature of the inner space of the electronic device 100. Therefore, the ventilation structure 110 may be used for heat dissipation, which helps to stabilize the operation performance of the electronic device 100 or prolong the service life of the electronic device 100. For convenience, an example in which hot air is discharged from the electronic device 100 to the outside through the ventilation structure 110 will be described hereinafter.

In this embodiment, when the electronic device 100 is oriented according to the space defined by the XYZ directions in FIG. 1, the positive Z direction represents the vertical upward direction, and the negative Z direction represents the vertical downward direction. The first opening 110A is located at the bottom of the ventilation structure 110 to define a ventilation direction D1 facing the negative Z direction, but the disclosure is not limited thereto. In some embodiments, the angle between the ventilation direction D1 of the first opening 110A and the normal (for example, parallel to the Z direction) of the bottom surface of the electronic device 100 may be less than 90 degrees. That is, the ventilation direction D1 may be downward, but forms an acute angle with the negative Z direction and is neither parallel to the X direction nor parallel to the Y direction. When the electronic device 100 is installed outdoors, the ventilation direction D1 of the first opening 110A faces the negative Z direction to help reduce the situation that external water splashes and enters the electronic device 100 through the first opening 110A. For example, the external water, such as rain, mainly falls in the negative Z direction, and even if the external water splashes, the external water does not easily travel in the positive Z direction. Therefore, it is difficult for external water to enter the electronic device 100 through the first opening 110A. The ventilation structure 110 not only allows air to circulate to provide heat dissipation but also reduces the intrusion of external water into the electronic device 100, which helps to reduce the probability of damage to the electronic device 100 due to the intrusion of external water.

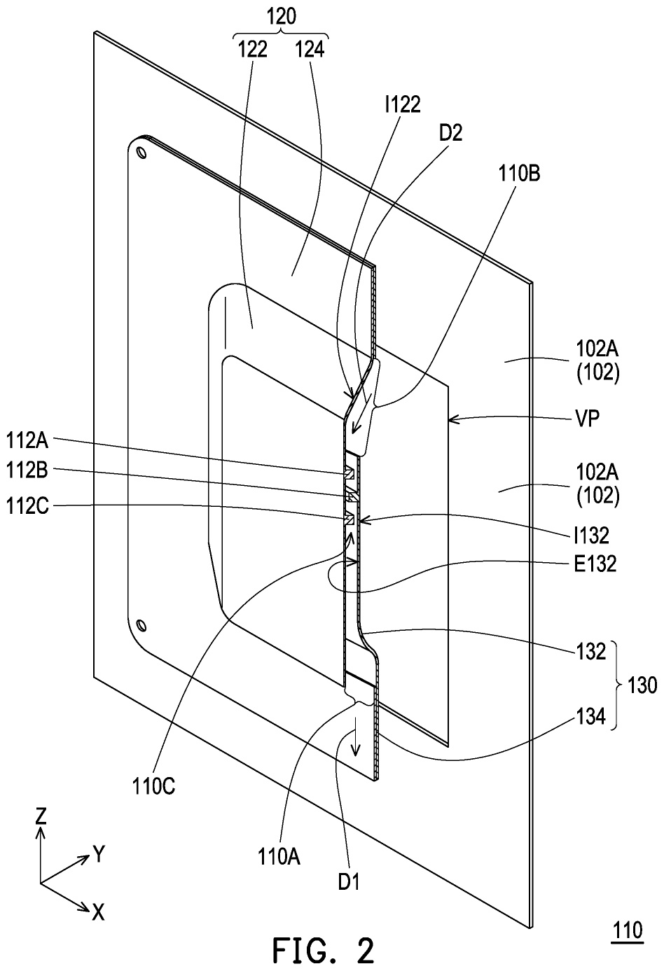

FIG. 2 is a partial enlarged view of the ventilation structure 110 of the electronic device of FIG. 1. In order to clearly illustrate the ventilation structure 110, FIG. 2 shows a part of the ventilation structure 110 cut along the line I-I of FIG. 1. As can be seen from FIG. 2, the back plate 102A of the casing 102 has a ventilation hole VP, and the ventilation structure 110 is arranged corresponding to the ventilation hole VP. Specifically, the ventilation structure 110 may block the ventilation hole VP. In some embodiments, the electronic device 100 may include a fan or a similar airflow guide member (not shown), and such an airflow guide member is generally arranged on the inner side surface of the back plate 102A and positioned at the ventilation hole VP. In this way, the airflow guide member and the ventilation structure 110 may provide effective heat dissipation. For example, the air inside the electronic device 100 may be guided to the ventilation hole VP by the airflow guide member, and then flow through the ventilation structure 110 from the ventilation hole VP to be discharged to the outside.

Specifically, the ventilation structure 110 also has a second opening 110B and a ventilation channel 110C connected between the first opening 110A and the second opening 110B in addition to the first opening 110A which can be observed from FIG. 1. The first opening 110A allows the ventilation channel 110C to communicate with the outside, and the second opening 110B allows the ventilation channel 110C to communicate with the inner space of the casing 102. That is to say, the ventilation channel 110C may be continuously distributed between the first opening 110A and the second opening 110B. The first opening 110A and the second opening 110B may be regarded as two ends of the ventilation channel 110C, and respectively connect the ventilation channel 110C with the outside and the inside of the electronic device 100. The air inside the electronic device 100 may enter the ventilation channel 110C through the second opening 110B and flow to the outside through the first opening 110A. In this embodiment, the ventilation direction D1 of the first opening 110A may be different from a ventilation direction D2 of the second opening 110B, but not limited thereto.

Additionally, the ventilation structure 110 may include a first barrier 112A, a second barrier 112B, and a third barrier 112C located in the ventilation channel 110C. The first barrier 112A, the second barrier 112B, and the third barrier 112C are sequentially arranged in the extending direction of the ventilation channel 110C, and the second barrier 112C is located between the first barrier 112A and the third barrier 112B. In this embodiment, the first barrier 112A, the second barrier 112B, and the third barrier 112C may alternately protrude from different sides of the ventilation channel 110C toward the center of the ventilation channel 110C. For example, as viewed from the cross section of FIG. 2, the first barrier 112A protrudes from the side of the ventilation channel 110C close to the outside toward the center of the ventilation channel 110C, the second barrier 112B protrudes from the side of the ventilation channel 110C away from the outside toward the center of the ventilation channel 110C, and the third barrier 112B protrudes from the side of the ventilation channel 110C close to the outside toward the center of the ventilation channel 110C. The first barrier 112A, the second barrier 112B, and the third barrier 112C arranged in the ventilation channel 110C make the ventilation channel 110C have a serpentine shape, which may further reduce the probability that the external water entering the ventilation channel 110C through the first opening 110A intrudes into the electronic device 100.

As can be seen from FIG. 2, the ventilation structure 110 further includes a first protection member 120 and a second protection member 130. The second protection member 130 is attached to the back plate 102A of the casing 102, and the first protection member 120 is attached to the second protection member 130. Therefore, the second protection member 130 is located between the first protection member 120 and the casing 102. A part of the first protection member 120 and a part of the second protection member 130 are separated from each other to define the ventilation channel 110C. That is, the ventilation channel 110C may be defined by the first protection member 120 and the second protection member 130, but not limited thereto. In addition, the first barrier 112A and the third barrier 112C may be arranged on the first protection member 120 closer to the outside, and the second barrier 112B may be arranged on the second protection member 130 far away from the outside (or close to the inside).

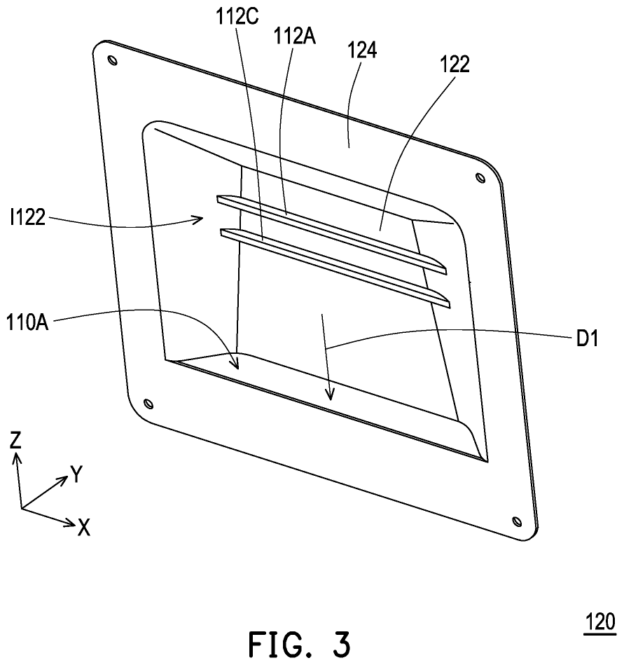

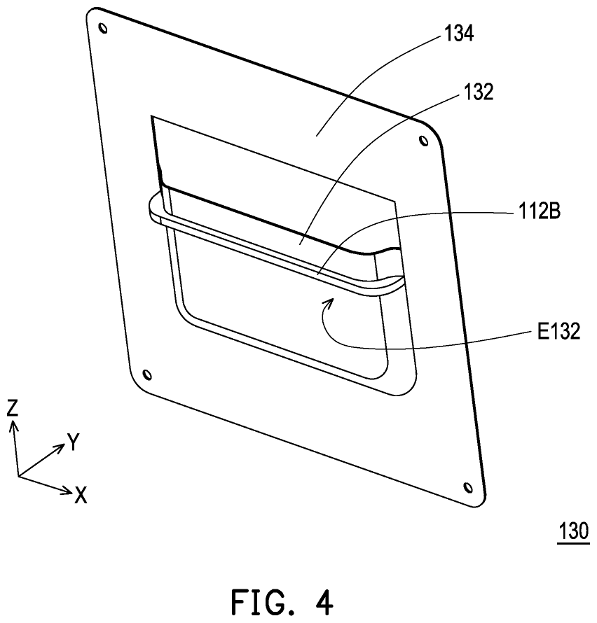

FIG. 3 is a schematic view of the first protection member 120 according to an embodiment, wherein FIG. 3 shows the inner side of the first protection member 120. FIG. 4 is a schematic view of the second protection member 130 according to an embodiment, wherein FIG. 4 shows the outer side of the second protection member 130. In this specification, the inner side refers to the side of the individual component close to the inner space of the electronic device 100 and the outer side refers to the side of the individual component opposite to the inner side. As can be seen from FIG. 2 and FIG. 3, the first protection member 120 may include a cover 122 and a flat plate 124. The flat plate 124 may surround the periphery of the cover 122, and the cover 122 protrudes from the flat plate 124 in a direction away from the back plate 102A of the casing 102, but the disclosure is not limited thereto. The cover 122 and the flat plate 124 may be integrally formed, or may be connected to each other by adhesion. The first barrier 112A and the third barrier 112C may be arranged on an inner side surface 1122 of the cover 122 and protrude from the inner side surface 1122 of the first protection member 120 toward the second protection member 130. The first barrier 112A and the third barrier 112C may be integrally formed with the cover 122, or may be attached to the cover 122 by adhesion, but not limited thereto. As shown in FIG. 3, the first barrier 112A and the third barrier 112C may be elongated ribs, but not limited thereto. In some embodiments, the first barrier 112A and the third barrier 112C may include a plurality of sections of ribs separated from each other. In addition, the materials of the first barrier 112A and the third barrier 112C may be the same as the material of the cover 122, but may also be different from the material of the cover 122.

As can be seen from FIG. 2 and FIG. 4, the second protection member 130 may include a cover 132 and a flat plate 134. The flat plate 134 may surround the cover 132 and be attached to the back plate 102A of the casing 102. The cover 132 and the flat plate 134 may be integrally formed, or may be connected to each other by adhesion. The cover 132 may protrude from the flat plate 134 in a direction away from the back plate 102A of the casing 102. Therefore, in FIG. 2, there is a separation space on the plane where the cover 132 and the ventilation hole VP on the back plate 102A are located. The second barrier 112B is arranged on an outer side surface E132 of the cover 132 and may protrude from the outer side surface E132 of the second protection member 130 toward the first protection member 120. The second barrier 112B may be integrally formed with the cover 132, or may be attached to the cover 132 by adhesion. As shown in FIG. 4, the second barrier 112B may be an elongated rib, but not limited thereto. In some embodiments, the second barrier 112B may be composed of a plurality of sections of ribs. In addition, the material of the second barrier 112B may be the same as the material of the cover 132, but may also be different from the material of the cover 132.

In this embodiment, the flat plate 124 of the first protection member 120 may overlap the flat plate 134 of the second protection member 130 in the normal direction thereof, and the flat plate 134 of the second protection member 130 may overlap the back plate 102A of the casing 102 in the normal direction thereof. In some embodiments, the flat plate 124 of the first protection member 120 may be attached to the flat plate 134 of the second protection member 130 by welding or adhesion, and the flat plate 134 of the second protection member 130 may be attached to the back plate 102A of the casing 102 by welding or adhesion. In some embodiments, the flat plate 124 of the first protection member 120 and the flat plate 134 of the second protection member 130 may be attached to the back plate 102A of the casing 102 by locking, but the flat plate 124 and the flat plate 134 are not necessarily attached in such a manner.

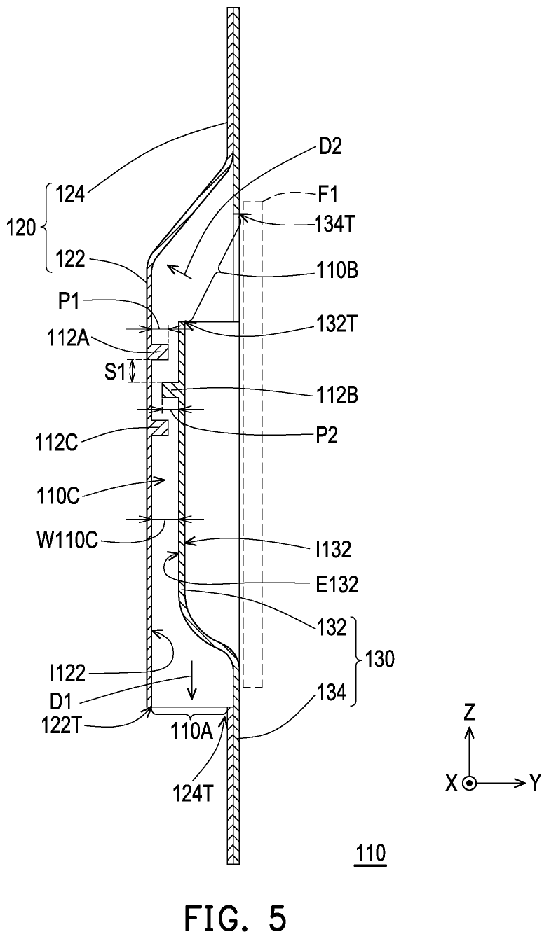

FIG. 5 is a side view of the ventilation structure 110 of the electronic device of FIG. 1 along the line I-I. Referring to FIG. 2 and FIG. 5, in some embodiments, the fan (not shown) in the electronic device 100 may be installed at an installation position F1 marked in FIG. 5, and the fan may guide the air inside the electronic device 100 to the ventilation hole VP and then the guided air may be discharged to the outside of the electronic device 100 through the ventilation structure 110.

In this embodiment, the cover 122 of the first protection member 120 and the cover 132 of the second protection member 130 are separated from each other to define the ventilation channel 110C. The cover 122 of the first protection member 120 has an open edge 122T that is not connected to the flat plate 124, and the open edge 122T and an edge 124T of the flat plate 124 may define the first opening 110A. Furthermore, the cover 132 of the second protection member 130 has an open edge 132T that is not connected to the flat plate 134, and the open edge 132T and an edge of the flat plate 134 may define the second opening 110B. The ventilation direction D1 of the first opening 110A and the ventilation direction D2 of the second opening 132 may be different. Therefore, after the air inside the casing 102 flows out of the ventilation hole VP, the air may first be collected at the second opening 110B along the inner side surface 1132 of the cover 132 of the second protection member 130, flow into the ventilation channel 110C at the second opening 110B, and then meander following the first barrier 112A, the second barrier 112B, and the third barrier 112C along the ventilation channel 110C toward the first opening 110A to be discharged out of the casing 102 through the first opening 110A.

In this embodiment, the first barrier 112A, the second barrier 112B, and the third barrier 112C at least partially overlap in the extending direction of the ventilation channel 110C. For example, a protruding height P1 of the first barrier 112A from the cover 122 of the first protection member 120 toward the second protection member 130 may be greater than half of a width W110C of the ventilation channel 110C, and the third barrier 112C has a similar structural design. Similarly, a protruding height P2 of the second barrier 112B from the outer surface of the cover 132 of the second protection member 130 toward the first protection member 120 may be greater than half of the width W110C of the ventilation channel 110C. In addition, the protruding height P1 and the protruding height P2 are both less than the width W110C to ensure that the ventilation channel 110C is not blocked. Here, the width W110C of the ventilation channel 110C may be understood as the minimum separation distance between the inner side surface 1122 of the cover 122 of the first protection member 120 and the outer side surface E132 of the cover 132 of the second protection member 130 in a direction (Y direction) perpendicular to the channel extending direction, and the protruding height of the barrier is the maximum height of the barrier measured along the same direction (Y direction). In some embodiments, the protruding height P1 or the protruding height P2 may be 55% to 60% of the width W110C, but not limited thereto.

In some embodiments, the sum of the protruding height P1 and the protruding height P2 is greater than the width W110C, but not both the protruding height P1 and the protruding height P2 are greater than half of the width W110C, which still allows the first barrier 112A, the second barrier 112B, and the third barrier 112C to at least partially overlap in the extending direction of the ventilation channel 110C. For example, one of the protruding height P1 and the protruding height P2 may be 45% of the width W110C, and the other one may be 60% of the width W110C, but not limited thereto. As can be seen from FIG. 5, the first barrier 112A, the second barrier 112B, and the third barrier 112C make the ventilation channel 110C meander. Therefore, if external water splashes and enters the ventilation channel 110C through the first opening 110A, the first barrier 112A, the second barrier 112B, and the third barrier 112C block the external water that has entered, thereby reducing the situation that external water enters the electronic device 100. In addition, the curved profile of the cover 132 of the second protection member 130 near the first opening 110A also helps to block external water from entering.

In this embodiment, the second barrier 112B is located between the first barrier 112A and the third barrier 112C, and a separation distance S1 between the second barrier 112B and the first barrier 112A may be the same as a separation distance between the second barrier 112B and the third barrier 112C. That is to say, the first barrier 112A, the second barrier 112B, and the third barrier 112C may be arranged at equal intervals in the extending direction (for example, Z direction) of the ventilation channel 110C, but not limited thereto. In some embodiments, the separation distances between two adjacent barriers may be different. It should be noted that the separation distance S1 may be defined as the shortest distance between two adjacent barriers in the extending direction (for example, Z direction) of the ventilation channel 110C. More specifically, in order to improve the smoothness of air flow, the separation distance S1 needs to be greater than or equal to the difference between the width of the ventilation channel 110C and the protruding height of each barrier. For example, the separation distance S1 between the first barrier 112A and the second barrier 112B is greater than or equal to the difference between the channel width W110C and the protruding height P1 of the first barrier 112A. If the difference is not a fixed value due to design, the separation distance S1 needs to be greater than or equal to the minimum value of the differences. If the separation distance between the barriers is not a fixed value due to design, the minimum value of the separation distances needs to be greater than or equal to the minimum value of the differences.

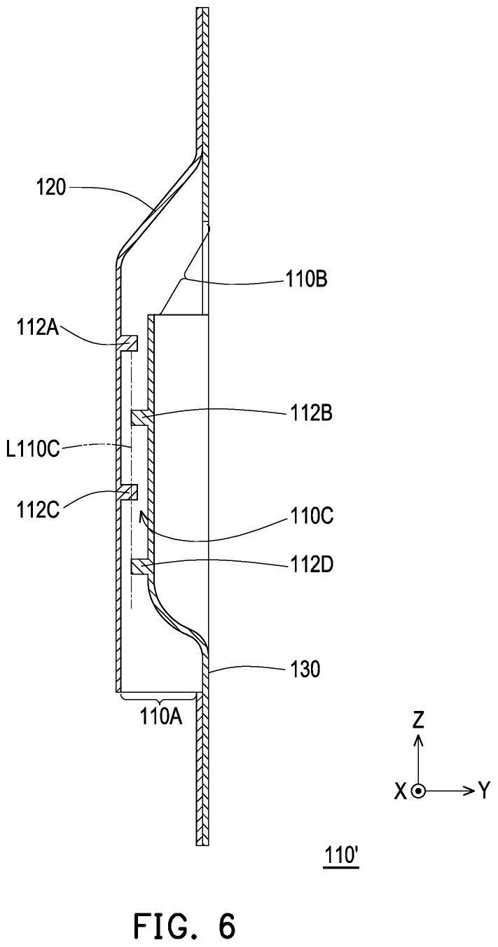

FIG. 6 is a schematic view of the ventilation structure according to an embodiment of the disclosure. The ventilation structure 110′ of FIG. 6 is similar to the ventilation structure 110 of FIG. 5. Therefore, in the two embodiments, the same reference numerals are used to represent the same components, and the same parts as the ventilation structure 110 will not be described again. In short, the ventilation structure 110′ is different from the ventilation structure 110 mainly in the number of barriers in the ventilation channel 110C and the intervals between the barriers. As shown in FIG. 6, the first barrier 112A, the second barrier 112B, the third barrier 112C, and a fourth barrier 112D are sequentially arranged in the extending direction of the ventilation channel 110C, and at least partially overlap in the extending direction of the ventilation channel 110C. The second barrier 112B and the fourth barrier 112D are arranged on the outer side surface of the second protection member 130 facing the first protection member 120 and protrude from the second protection member 130 toward the first protection member 120. The first barrier 112A, the second barrier 112B, the third barrier 112C, and the fourth barrier 112D are separated at equal intervals in the extending direction of the ventilation channel 110C, but not limited thereto.

The ventilation channel 110C conforms to the first barrier 112A, the second barrier 112B, the third barrier 112C, and the fourth barrier 112D to form a serpentine flow path. The protruding heights of the first barrier 112A, the second barrier 112B, the third barrier 112C, and the fourth barrier 112D toward the center of the ventilation channel 110C may be designed such that the first barrier 112A and the third barrier 112C at least partially overlap the second barrier 112B and the fourth barrier 112D in the extending direction of the ventilation channel 110C. For example, the respective protruding heights of the first barrier 112A, the second barrier 112B, the third barrier 112C, and the fourth barrier 112D may be greater than half of the width of the ventilation channel 110C. Accordingly, an imaginary straight line L110C along the extending direction of the ventilation channel 110C passes through the first barrier 112A, the second barrier 112B, the third barrier 112C, and the fourth barrier 112D. In other embodiments, the number of barriers provided on the first protection member 120 and the second protection member 130 may be changed according to different designs, and is not limited to the number described in the above embodiment.

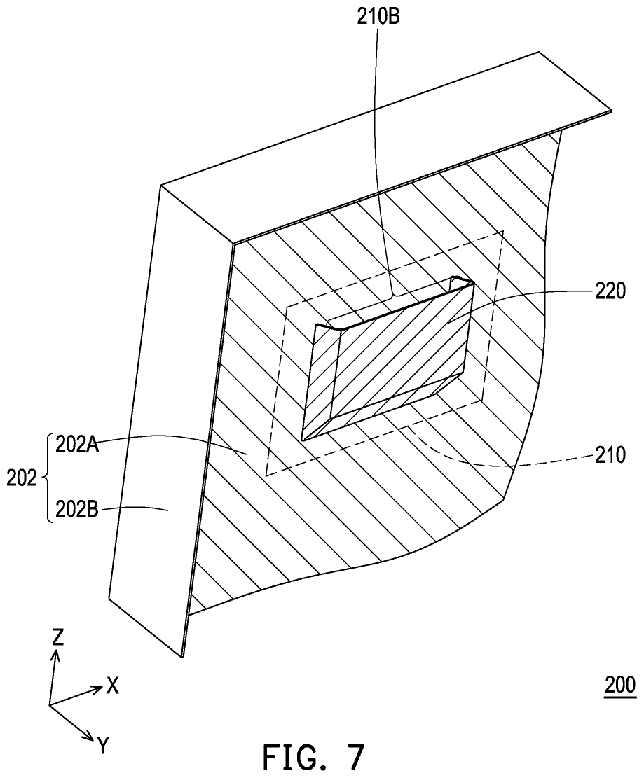

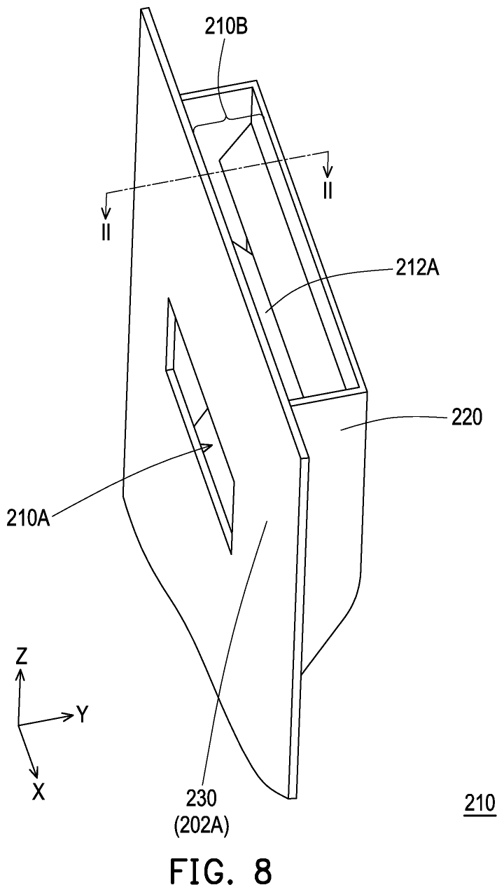

FIG. 7 is a partial schematic view of the electronic device according to an embodiment of the disclosure, wherein FIG. 7 shows the inner space of the electronic device, but the internal components of the electronic device are omitted. FIG. 8 is a schematic view of the ventilation structure of the electronic device of FIG. 7. In FIG. 7, the electronic device 200 includes a casing 202 and a ventilation structure 210. The casing 202 has a back plate 202A and a side wall 202B surrounding the periphery of the back plate 202A. The casing 202 may enclose the inner space of the electronic device 200 to accommodate electronic components or other components of the electronic device 200. The ventilation structure 210 may be arranged on the back plate 202A of the casing 202. Referring to FIG. 7 and FIG. 8, the ventilation structure 210 may define a first opening 210A, a second opening 210B, and a ventilation channel connected between the first opening 210A and the second opening 210B (not shown in FIG. 7 and FIG. 8). The first opening 210A is exposed outside the casing 202 and the second opening 210B is located in the inner space of the electronic device enclosed by the casing 202.

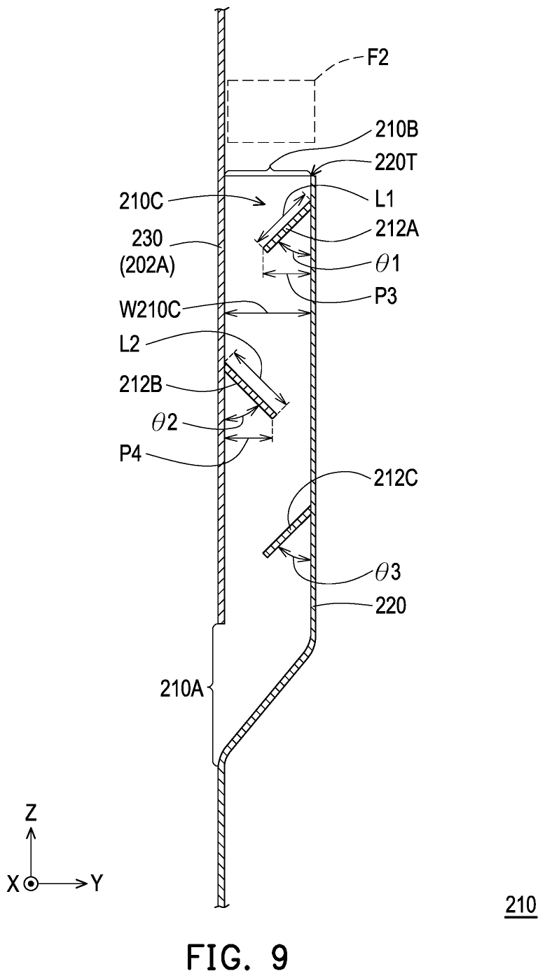

FIG. 9 is a schematic cross-sectional view of the ventilation structure of FIG. 8 along the line II-II. In some embodiments, the fan (not shown) in the electronic device 200 may be installed at an installation position F2 marked in FIG. 9, and the fan may guide the air inside the electronic device 200 to the ventilation structure 210 and discharge the air to the outside through the ventilation structure 210, but the disclosure is not limited thereto. In the disclosure, the fan may be installed at any position that can smoothly discharge the hot air inside the electronic device. Referring to FIG. 8 and FIG. 9, the ventilation structure 210 has the first opening 210A, the second opening 210B, and the ventilation channel 210C, and the first opening 210A and the second opening 210B are located at two ends of the ventilation channel 210C. As shown in FIG. 8, the first opening 210A is visible on the exterior of the electronic device 200, and the second opening 210B may be located inside the electronic device 200. The first opening 210A allows the ventilation channel 210C to communicate with the outside of the electronic device 200, and the second opening 210B allows the ventilation channel 210C to communicate with the inside of the electronic device 200. Therefore, the ventilation structure 210 contributes to the heat dissipation of the electronic device 200.

In addition, the ventilation structure 210 includes a first barrier 212A, a second barrier 212B, and a third barrier 212C located in the ventilation channel 210C. The first barrier 212A, the second barrier 212B, and the third barrier 212C enable the ventilation channel 210C to provide a serpentine flow path, and at least partially overlap in the extending direction of the ventilation channel 210C. Accordingly, the external water entering the ventilation channel 210C through the first opening 210A may be blocked by the first barrier 212A, the second barrier 212B, and the third barrier 212C and prevented from entering the inner space of the electronic device 200 through the second opening 210B. Therefore, the ventilation structure 210 may reduce the damage to the electronic device 200 due to the intrusion of external water.

The ventilation structure 210 further includes a first protection member 220 and a second protection member 230, and the ventilation channel 210C may be defined by the first protection member 220 and the second protection member 230. In this embodiment, the first protection member 220 is attached to the second protection member 230, and the second protection member 230 may be a part of the back plate 202A. Therefore, the second protection member 230 can be integrally formed with the casing 202 (marked in FIG. 7). In some embodiments, the first protection member 220 may be attached to the inner surface of the back plate 202A by welding, locking, or adhesion such that a part of the back plate 202A overlapping the first protection member 220 may be defined as the second protection member 230. The first protection member 220 and the second protection member 230 may partially overlap each other but not close to each other so as to enclose the ventilation channel 210C. In addition, the first opening 210A is an open structure opened on the back plate 202A, and the second opening 210B may be defined by an open edge 220T of the first protection member 220.

The first barrier 212A and the third barrier 212C are arranged on the first protection member 220 and the second barrier 212B is arranged on the second protection member 230. The first barrier 212A and the third barrier 212C protrude from the first protection member 220 toward the second protection member 230 without contacting the second protection member 230, and the second barrier 212B protrudes from the second protection member 230 toward the first protection member 220 without contacting the first protection member 220. Accordingly, none of the first barrier 212A, the second barrier 212B, and the third barrier 212C closes the ventilation channel 210C such that the ventilation channel 210C extends continuously between the first opening 210A and the second opening 210B. The first barrier 212A, the second barrier 212B, and the third barrier 212C define a serpentine flow path in the ventilation channel 210C. It should be noted that, in this embodiment, as long as a serpentine flow path can be defined in the ventilation channel 210C, the number and positions of the barriers in the ventilation channel are not particularly limited. For example, in some embodiments, the first barrier 212A and the third barrier 212C may be located on the second protection member 220 and protrude toward the first protection member 230, and the second barrier 212B may be located on the first protection member 230 and protrude toward the second protection member 220; and in some embodiments, more than three barriers may be included in the ventilation channel 210C.

The first barrier 212A and the third barrier 212C are inclined barriers. For example, an angle θ1 between the first barrier 212A and the first protection member 220 may be greater than 0 degrees and less than 90 degrees (0°<θ1<90°). In other words, the distance between the first barrier 212A and the first opening 210A in the Z direction decreases as the first barrier 212A goes away from the first protection member 220. The structure of the third barrier 212C may be similar to the structure of the first barrier 212A. In addition, an angle θ2 between the second barrier 212B and the second protection member 230 may be greater than 0 degrees and less than 90 degrees (0°<θ2<90°). The distance between the second barrier 212B and the first opening 210A in the Z direction decreases as the second barrier 212B goes away from the second protection member 230. If the first opening 210A is regarded as the downstream end of the ventilation channel 210C, the first barrier 212A, the second barrier 212B, and the third barrier 212C all have a structure inclined toward the downstream. The angle θ1 between the first barrier 212A and the first protection member 220, the angle θ2 between the second barrier 212B and the second protection member 230, and an angle θ3 between the third barrier 212C and the first protection member 220 may be the same as, partially the same as, or different from each other. In some embodiments, the angle θ1, the angle θ2, and the angle θ3 may be any angle from 0 degrees to 90 degrees, for example, 30 degrees, 45 degrees, 50 degrees, 55 degrees, 60 degrees, 70 degrees, 75 degrees, and 80 degrees.

In this embodiment, the first barrier 212A, the second barrier 212B, and the third barrier 212C at least partially overlap in the extending direction of the ventilation channel 210C. For example, the first barrier 212A has a protruding height P3 from the first protection member 220 toward the second protection member 230, and the second barrier 212B has a protruding height P4 from the second protection member 230 toward the first protection member 220. The directions for measuring the protruding height P3 and the protruding height P4 are approximately the same as the direction for measuring the width W210C of the ventilation channel 110C. Both the protruding height P3 and the protruding height P4 are less than the width W210C to ensure that the ventilation channel 110C is not blocked. In some embodiments, the sum of the protruding height P3 and the protruding height P4 is greater than the width W210C. In some embodiments, at least one of the protruding height P3 and the protruding height P4 is greater than half of the width W210C. In some embodiments, the first barrier 212A is an inclined barrier. Therefore, the protruding height P3 may be less than the extending length L1 of the first barrier 212A, and the protruding height P4 of the second barrier 212B may also be less than the extending length L2 of the second barrier 212B. Furthermore, the design of size of the third barrier 212C may be the same as the design of size of the first barrier 212A, but not limited thereto.

In the foregoing embodiments, the materials of the ventilation structure 110, the ventilation structure 110′, and the ventilation structure 210 may include metal, plastic, a printed material, or other solid materials. In some embodiments, different materials may be used to manufacture different parts of the ventilation structure 110, the ventilation structure 110′, or the ventilation structure 210. The materials of the ventilation structure 110, the ventilation structure 110′, or the ventilation structure 210 may be the same as, partially the same as, or completely different from the material of the casing 110 or 120. In addition, the ventilation structure 110, the ventilation structure 110′, and the ventilation structure 210 may be manufactured by three-dimensional printing, multi-component bonding, punching, or other mechanical manufacturing methods.

To sum up, the electronic device according to the embodiment of the disclosure includes the ventilation structure, and barriers are arranged in the ventilation channel defined by the ventilation structure. Accordingly, the air inside the electronic device may communicate with the outside through the ventilation structure to achieve heat dissipation, and external water is unlikely to enter the electronic device through the ventilation structure, thereby maintaining the operation performance of the electronic device or prolonging the service life of the electronic device. The design of the ventilation structure reduces the intrusion of external water. Therefore, the electronic device according to the embodiment of the disclosure can be installed in an outdoor environment, or may not be easily damaged due to weather factors such as rain. In other words, the electronic device according to the embodiment of the disclosure has favorable environmental resistance.

Finally, it should be noted that the above embodiments are intended to illustrate rather than limit the technical solutions of the disclosure. Although the disclosure has been described in detail with reference to the foregoing embodiments, people having ordinary knowledge in the art should understand that it is possible to modify the technical solutions described in the foregoing embodiments, or equivalently replace some or all of the technical features. However, such modifications or replacements do not make the essence of the corresponding technical solutions deviate from the scope of the technical solutions of the embodiments of the disclosure.

What is claimed is:

1. An electronic device, comprising:
a casing; and
a ventilation structure located on the casing and having a first opening, a second opening, and a ventilation channel connected between the first opening and the second opening,
wherein the ventilation structure comprises a first barrier, a second barrier, and a third barrier located in the ventilation channel,
the second barrier is located between the first barrier and the third barrier, and
the first barrier, the second barrier, and the third barrier at least partially overlap in an extending direction of the ventilation channel.

2. The electronic device according to claim 1, wherein the ventilation structure further comprises a first protection member and a second protection member,
the first protection member and the second protection member at least partially overlap to enclose the ventilation channel, and
the first barrier and the third barrier are arranged on one of the first protection member and the second protection member, and the second barrier is arranged on the other one of the first protection member and the second protection member.

3. The electronic device according to claim 2, wherein the first barrier and the third barrier protrude from the one of the first protection member and the second protection member toward the other one of the first protection member and the second protection member.

4. The electronic device according to claim 2, wherein the second barrier protrudes from the other one of the first protection member and the second protection member toward the one of the first protection member and the second protection member.

5. The electronic device according to claim 2, wherein the ventilation structure further comprises a fourth barrier, and
the fourth barrier is arranged on the other one of the first protection member and the second protection member, and protrudes toward the one of the first protection member and the second protection member.

6. The electronic device according to claim 2, wherein the first protection member comprises a cover and a flat plate,
the flat plate surrounds a periphery of the cover, and
the cover protrudes from the flat plate in a direction away from the casing.

7. The electronic device according to claim 6, wherein the cover has an open edge that is not connected to the flat plate, and the open edge and an edge of the flat plate define the first opening.

8. The electronic device according to claim 6, wherein the second protection member comprises a cover and a flat plate,
the flat plate of the second protection member surrounds the cover of the second protection member and is attached to the casing, and
the cover of the first protection member and the cover of the second protection member are separated from each other to define the ventilation channel.

9. The electronic device according to claim 1, wherein a separation distance from the second barrier to the first barrier is the same as a separation distance from the third barrier to the second barrier.

10. The electronic device according to claim 1, wherein a protruding height of at least one of the first barrier, the second barrier, and the third barrier is greater than half of a width of the ventilation channel.

11. The electronic device according to claim 1, wherein a separation distance from the second barrier to the first barrier is greater than or equal to a difference between a width of the ventilation channel and a protruding height of the first barrier.

12. The electronic device according to claim 1, wherein the first barrier, the second barrier,
and the third barrier are inclined barriers.

13. The electronic device according to claim 1, wherein the casing has a ventilation hole,
and the ventilation structure is arranged corresponding to the ventilation hole.

14. The electronic device according to claim 1, wherein the casing at least comprises a back plate and a side wall,
the side wall surrounds a periphery of the back plate to enclose an inner space, and
the ventilation structure allows air communication between the inner space and outside.

15. The electronic device according to claim 14, wherein the back plate has a ventilation hole, and the ventilation structure is arranged corresponding to the ventilation hole.

16. The electronic device according to claim 1, wherein the ventilation channel has a serpentine shape.

17. The electronic device according to claim 1, wherein a ventilation direction of the first opening is different from a ventilation direction of the second opening.

18. The electronic device according to claim 1, wherein the first barrier, the second barrier, and the third barrier alternately protrude from different sides of the ventilation channel toward a center of the ventilation channel.

19. The electronic device according to claim 1, wherein the first opening is exposed outside the casing, and the second opening is located in an inner space of the electronic device enclosed by the casing.

20. The electronic device according to claim 1, wherein a protruding height of the first barrier is less than an extending length of the first barrier.
